(19) United States
(12) Patent Application Publication
(10) Pub. No.: US 2024/0196678 A1
(43) Pub. Date: Jun. 13, 2024

(54) DISPLAY DEVICE

(71) Applicant: LG Display Co., Ltd., Seoul (KR)

(72) Inventors: Jeon Phill HAN, Paju-si (KR); Yong In PARK, Paju-si (KR); Seung Han PAEK, Paju-si (KR); Eui Hyun CHUNG, Paju-si (KR)

(21) Appl. No.: 18/515,000

(22) Filed: Nov. 20, 2023

(30) Foreign Application Priority Data
Dec. 13, 2022 (KR) 10-2022-0173276

(51) Int. Cl. H10K 59/131

(52) U.S. Cl. CPC H10K 59/131; H10K 2102/351

(57) ABSTRACT

Embodiments disclose a display device including a substrate including a display region and a non-display region, a signal wiring connected to the display region, a test wiring connected to the signal wiring, and an etch stop layer disposed between the substrate and the test wiring, wherein a width of the etch stop layer is greater than a width of the test wiring.

### CROSS-REFERENCE TO RELATED APPLICATION

This application claims priority to and the benefit of Korean Patent Application No. 10-2022-0173276, filed on Dec. 13, 2022, the disclosure of which is incorporated herein by reference in its entirety.

### BACKGROUND

### Technical Field

Embodiments relate to a display device.

### Description of the Related Art

Electroluminescence display devices are classified into inorganic light-emitting display devices and organic light-emitting display devices depending on materials of a light-emitting layer. An active-matrix-type organic light-emitting display device includes an organic light-emitting diode (OLED) that emits light by itself and has advantages in terms of a quick response time, high luminous efficiency, high luminance, and a wide viewing angle. The organic light-emitting display device has OLEDs formed in each pixel. The organic light-emitting display device may represent a black grayscale as perfect black as well as having a quick response time, high luminous efficiency, high luminance, and a wide viewing angle, and thus has an excellent contrast ratio and color gamut.

During a process of manufacturing a display device, a test process (also referred to as an auto-probe process) is performed to test whether a display panel is driven normally and lights up normally. For this test process, test wirings and test pads, which are connected to signal wirings related to driving, are disposed.

Recently, organic light-emitting display devices have been implemented on a plastic substrate, which is a flexible material, but may also be implemented on a glass substrate due to various issues. The glass substrate can be processed into various shapes by selectively etching the glass substrate using an etching solution.

### BRIEF SUMMARY

Inventors recognized that test wirings may be exposed to an etching solution in the process of etching the glass substrate, and the test wirings may be broken, which makes it difficult to test a display panel. Embodiments provide a display device with improved test reliability of a display panel.

It should be noted that the technical features of the present disclosure is not limited to those above-described, and other technical features of the present disclosure will be apparent to those skilled in the art from the following descriptions.

According to an aspect of the present disclosure, there is provided a display device including a substrate including a display region and a non-display region, a signal wiring connected to the display region, a test wiring connected to the signal wiring, and an etch stop layer disposed below the test wiring, wherein a width of the etch stop layer is greater than a width of the test wiring.

The etch stop layer may include a center region overlapping the test wiring and an edge region not overlapping the test wiring.

A width of the edge region may be less than a width of the center region.

A thickness of the edge region may be less than a thickness of the center region.

The display device may include a first inorganic insulating film disposed between the etch stop layer and the test wiring.

The display device may include an organic insulating film disposed on the test wiring and configured to cover the edge region and a side surface of the etch stop layer.

The display device may include a second inorganic insulating film disposed between the organic insulating film and the test wiring.

The test wiring may include a plurality of test wirings connected to a plurality of signal wirings, and the etch stop layer may overlap some of the plurality of test wirings.

The display device may include an inorganic insulating pattern layer disposed on the edge region of the etch stop layer, wherein a material of the inorganic insulating pattern layer may be the same as a material of the first inorganic insulating film.

A thickness of the inorganic insulating pattern layer may be different from a thickness of the first inorganic insulating film.

A side surface of the substrate may have an inclination, and the etch stop layer may protrude further outward than the side surface of the substrate.

The display device may include a coating layer disposed on a lower surface of the substrate, the side surface of the substrate, and a lower surface of the etch stop layer protruding from the side surface of the substrate.

A side surface of the coating layer may be disposed to be coplanar with a side surface of the etch stop layer.

The display region may include a first semiconductor layer, a first gate insulating film disposed on the first semiconductor layer, a first gate electrode disposed on the first gate insulating film, and a first insulating film disposed on the first gate electrode, and the etch stop layer may be formed on the same layer as the first gate electrode.

The display region may include a second semiconductor layer disposed on the first insulating film, and a second gate electrode disposed on the second semiconductor layer, and the test wiring may be formed on the same layer as the second gate electrode.

### BRIEF DESCRIPTION OF THE SEVERAL VIEWS OF THE DRAWINGS

The above and other objects, features, and advantages of the present disclosure will become more apparent to those of ordinary skill in the art by describing exemplary embodiments thereof in detail with reference to the accompanying drawings, in which:

FIG. 1 is a conceptual diagram of a display panel according to one embodiment of the present disclosure;

FIG. 2 is a view illustrating a test panel according to one embodiment of the present disclosure;

FIG. 3 is a cross-sectional view taken along line Y-Y′ of FIG. 2;

FIG. 4 is a view illustrating a final cross-sectional structure of a display panel from which the test panel is cut out;

FIG. 5 is a cross-sectional view taken along line X-X′ of FIG. 2;

FIG. 6A is a view illustrating a test wiring structure according to a first embodiment of the present disclosure;

FIG. 6B is a plan view of FIG. 6A;

FIG. 7A is a view illustrating a test wiring of a conventional structure;

FIG. 7B is a view illustrating a state in which the test wiring is separated from a panel when a substrate is etched;

FIG. 7C is a photograph showing a state in which the test wiring is separated from the panel when the substrate is etched;

FIG. 8 is a view illustrating a state in which the test wiring is disconnected by the substrate etching;

FIG. 9A is a view illustrating a test wiring structure according to a second embodiment of the present disclosure;

FIG. 9B is a modified example of FIG. 9A;

FIG. 10A is a view illustrating a test wiring structure according to a third embodiment of the present disclosure;

FIG. 10B is a plan view of FIG. 10A;

FIG. 11 is a view illustrating a test wiring structure according to a fourth embodiment of the present disclosure;

FIG. 12 is a view illustrating a test wiring structure according to a fifth embodiment of the present disclosure;

FIGS. 13A to 13H are views illustrating various inorganic insulating film patterns of FIG. 12;

FIG. 14 is a view illustrating a pixel structure according to one embodiment of the present disclosure;

FIG. 15 is a view illustrating a test wiring structure according to a sixth embodiment of the present disclosure;

FIG. 16 is a view illustrating a test wiring structure according to a seventh embodiment of the present disclosure;

FIG. 17 is a view illustrating a test wiring structure according to an eighth embodiment of the present disclosure;

FIG. 18 is a view illustrating a test wiring structure according to a ninth embodiment of the present disclosure;

FIGS. 19A to 19G are views illustrating a process of forming the test wiring;

FIG. 20 is a photograph showing a manufactured test wiring;

FIG. 21 is a view illustrating a state in which a lower portion of a substrate is etched;

FIG. 22 is a view showing a cross section of a test wiring region after the substrate is removed; and

FIG. 23 is a photograph showing a cross section taken along line A-A of FIG. 22.

### DETAILED DESCRIPTION

Advantages and features of the present disclosure and implementation methods thereof will be clarified through the following embodiments described with reference to the accompanying drawings. However, the present disclosure is not limited to the embodiments described below and may be implemented with a variety of different forms. The embodiments are merely provided to allow those skilled in the art to completely understand the scope of the present disclosure.

The figures, dimensions, ratios, angles, numbers, and the like disclosed in the drawings for describing the embodiments of the present disclosure are merely illustrative and are not limited to details shown in the present disclosure. Throughout the specification, like reference numerals refer to like elements. Further, in describing the present disclosure, detailed descriptions of well-known technologies will be omitted when it is determined that they may unnecessarily obscure the gist of the present disclosure.

Terms such as “including,” “having,” and “composed of” used herein are intended to allow other elements to be added unless the terms are used with the term “only.” When a component is expressed in the singular form, it may include a case in which the plural form is included unless otherwise explicitly stated.

Components are interpreted as including an ordinary error range even if not expressly stated.

For description of a positional relationship, for example, when the positional relationship between two parts is described as “on,” “above,” “below,” and “next to,” or the like, one or more parts may be interposed therebetween unless the term “immediately” or “directly” is used in the expression.

In the description of embodiments, the terms “first,” “second,” and the like may be used herein to describe various components, the components are not limited by the terms. These terms are used only to distinguish one component from another. Accordingly, a first component described below could be termed a second component without departing from the technical spirit of the present disclosure.

Throughout the specification, like reference numerals refer to like elements.

The features of various embodiments may be partially or entirely combined with each other. The embodiments may be interoperated and performed in technically various ways and may be carried out independently of or in association with each other.

A pixel circuit and a gate driving part formed on a display panel of the present disclosure may include a plurality of transistors. The transistors may be implemented as oxide thin-film transistors (TFTs) including an oxide semiconductor, low-temperature polysilicon (LTPS) TFTs including LTPS, and the like. In addition, each of the transistors may be implemented as a p-channel TFT or an n-channel TFT.

The transistor is a three-electrode element including a gate, a source, and a drain. Here, the source is an electrode that provides carriers to the transistor. In addition, the carriers in the transistor start to flow from the source. Further, the drain is an electrode through which the carriers exit from the transistor to the outside. In addition, in the transistor, the carriers flow from the source to the drain. In the case of an n-channel transistor, carriers are electrons, and thus a source voltage is lower than a drain voltage so that the electrons flow from the source to the drain. In this case, in the n-channel transistor, current flows from the drain to the source. In the case of a p-channel transistor (PMOS), carriers are holes, and thus a source voltage is higher than a drain voltage so that the holes flow from the source to the drain. In addition, in the p-channel transistor, since the holes flow from the source to the drain, current flows from the source to the drain. It should be noted that the source and the drain of the transistor are not fixed in position. For example, the source and the drain are interchangeable depending on the applied voltage. Accordingly, the present disclosure is not limited by the source and the drain of the transistor. In the following description, the source and the drain of the transistor will be referred to as a first electrode and a second electrode, respectively.

A gate signal swings between a gate-on voltage and a gate-off voltage. Here, the gate-on voltage is set to be higher than a threshold voltage of the transistor, and the gate-off voltage is set to be lower than the threshold voltage of the transistor. The transistor is turned on in response to the gate-on voltage and turned off in response to the gate-off voltage. In the case of an n-channel transistor, the gate-on voltage may be a gate high voltage VGH/VEH, and the gate-off voltage may be a gate low voltage VGL/VEL. In the case of a p-channel transistor, the gate-on voltage may be the gate low voltage VGL/VEL, and the gate-off voltage may be the gate high voltage VGH/VEH.

Hereinafter, various embodiments of the present disclosure will be described in detail with reference to the accompanying drawings.

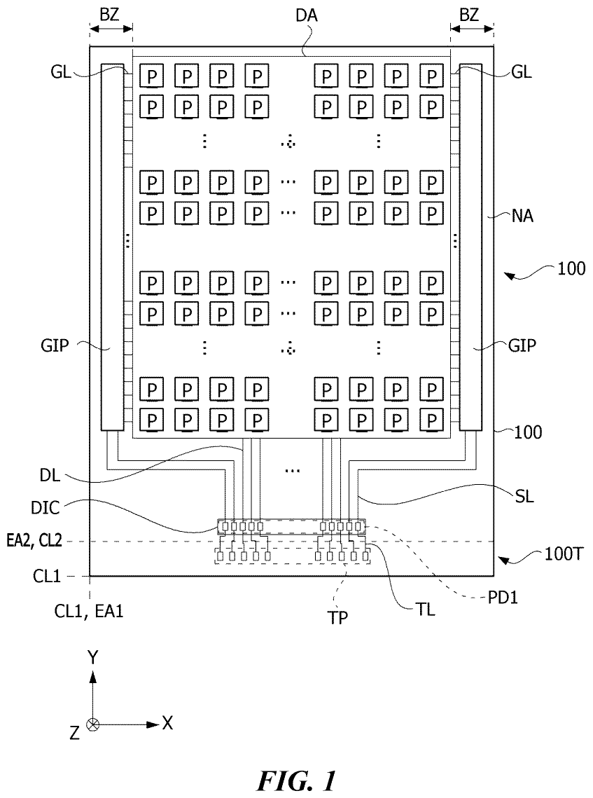

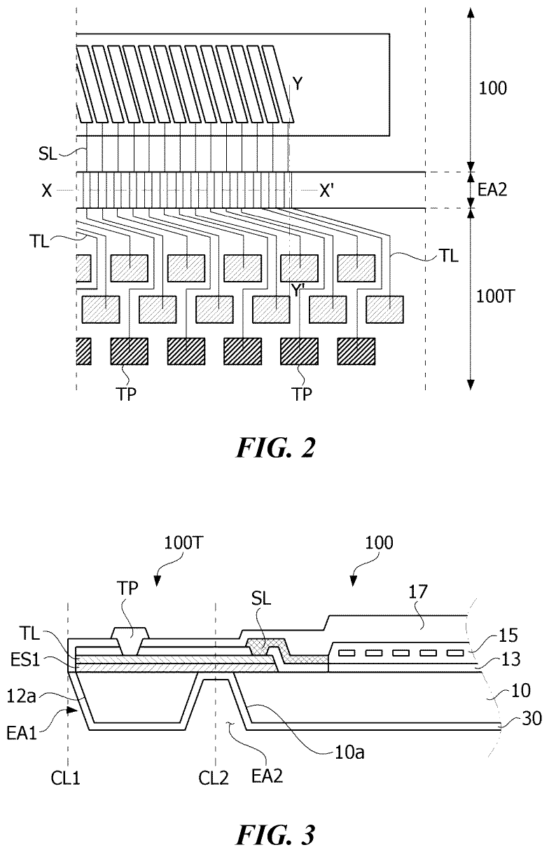

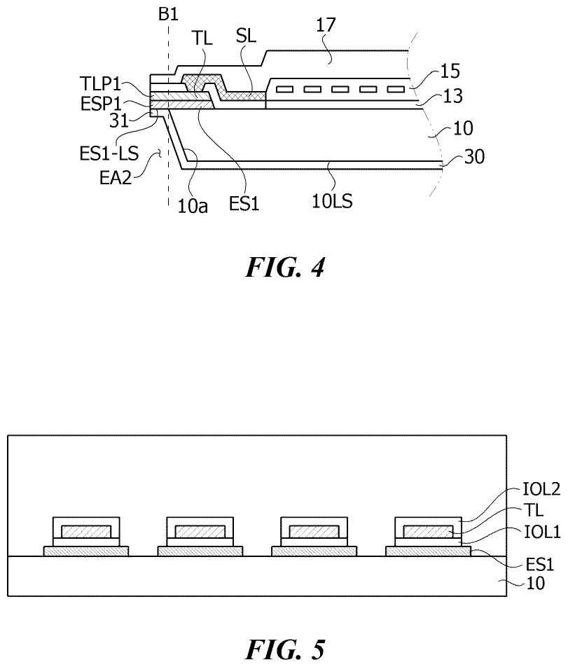

FIG. 1 is a conceptual diagram of a display panel according to an embodiment of the present disclosure. FIG. 2 is a view illustrating a test panel region according to one embodiment of the present disclosure. FIG. 3 is a cross-sectional view taken along line Y-Y′ of FIG. 2.

Referring to FIGS. 1 and 2, the display device according to the embodiment of the present disclosure may include a display panel 100 including a display region DA, and a plurality of signal wirings SL formed on the display panel 100.

The display region DA of the display panel 100 may include data lines DL, gate lines GL crossing the data lines DL, and pixels P arranged in a matrix form defined by the data lines DL and the gate lines GL. The signal wirings SL are a concept that includes the data lines DL and the gate lines GL. In addition, the display panel 100 may include a bezel region that is a non-display region NA outside the display region DA.

Each of the pixels P includes sub-pixels having different colors for color implementation. The sub-pixels include red (hereinafter referred to as “R sub-pixel”), green (hereinafter referred to as “G sub-pixel”), and blue (hereinafter referred to as “B sub-pixel”). Although not shown in the drawings, each of the pixels P may further include a white sub-pixel. Hereinafter, a pixel may be interpreted as a sub-pixel unless otherwise defined. In addition, each of the sub-pixels may include a pixel circuit.

The pixel circuit may include a light-emitting element, a driving element configured to supply a current to the light-emitting element, one or more switch elements configured to switch current paths between the driving element and the light-emitting element, a capacitor configured to maintain a gate-source voltage Vgs of the driving element, and the like.

The light-emitting element may be implemented as an organic light-emitting diode (OLED). The OLED includes an organic compound layer formed between an anode and a cathode. The organic compound layer may include a hole injection layer HIL, a hole transport layer HTL, an emission layer EML, an electron transport layer ETL, and an electron injection layer EIL, but the present disclosure is not limited thereto. When a voltage is applied to the anode and the cathode of the OLED, holes passing through the hole transport layer HTL and electrons passing through the electron transport layer ETL move to the emission layer EML to create excitons, and thus visible light is emitted from the light-emitting layer EML.

A display panel driving part writes pixel data of an input image to the pixels P. The display panel driving part includes a data driving part configured to supply a data voltage of the pixel data to the data lines DL, and a gate driving part GIP configured to sequentially supply a gate pulse to the gate lines GL. The data driving part is integrated into a drive integrated circuit (IC) DIC. The drive IC DIC may be adhered to the display panel 100.

The drive IC DIC is connected to the data lines DL through data output channels to supply a voltage of the data signal to the data lines. The drive IC DIC includes a timing controller. The timing controller transmits pixel data of an input image received from a host system to the data driving part, and controls operation timings of the data driving part and the gate driving part GIP.

The data driving part of the drive IC DIC converts the pixel data into a gamma compensation voltage through a digital-to-analog converter (DAC) and outputs a data voltage.

The gate driving part GIP may include a shift register formed on a circuit layer of the display panel 100 together with a pixel array. The shift register of the gate driving part GIP sequentially supplies the gate signal to the gate lines GL under the control of the timing controller. The gate signal may include a scan pulse and an emission control pulse.

The display panel may be implemented as a flexible panel applicable to a flexible display. The flexible display may have a screen that is variable in size by rolling, folding, or bending the flexible panel, and may be easily manufactured with various designs.

The flexible display may be implemented as a rollable display, a foldable display, a bendable display, a slidable display, or the like.

The flexible panel may be manufactured as a so-called a “plastic OLED panel.” The plastic OLED panel may include a back plate and a pixel array formed on an organic thin film adhered to the back plate. A touch sensor array may be formed on the pixel array.

The back plate may be a polyethylene terephthalate (PET) substrate. The pixel array and the touch sensor array may be formed on the organic thin film. The back plate may block the permeation of moisture to the organic thin film so that the pixel array is not exposed to the moisture.

The organic thin film may be a polyimide (PI) substrate. A multi-layered buffer film may be formed of an insulating material (not shown) on the organic thin film.

The driving element of the pixel circuit may be implemented as a transistor. The driving element should have uniform electrical characteristics between all the pixels, but there may be differences in electrical characteristics between the pixels due to a process variation and an element characteristic variation, and the electrical characteristics may vary as a display driving time passes.

In order to compensate for the electrical characteristic variation of the driving element, the display device may include an internal compensation circuit and an external compensation circuit. The internal compensation circuit may be added to the pixel circuit in each of the sub-pixels to sample a threshold voltage Vth and/or a mobility u of the driving element, which vary according to the electrical characteristics of the driving element, and compensate for the variation in real time.

The external compensation circuit may transmit the threshold voltage and/or mobility of the driving element, which are sensed through a sensing line connected to each of the sub-pixels, to an external compensation part. The compensation part of the external compensation circuit may reflect the sensing result to modulate the pixel data of the input image, thereby compensating for the variation in electrical characteristics of the driving element.

A voltage of the pixel, which varies according to electrical characteristics of an external compensation driving element, may be sensed, and data of an input image may be modulated in an external circuit based on the sensed voltage, thereby compensating for the variation in electrical characteristics of the driving element between the pixels.

A test panel 100T on which test wirings TL and test pads TP are formed may be connected to a lower side of the display panel 100. The test panel 100T may be separated after a test process is completed.

The test wirings TL of the test panel 100T may be electrically connected to the signal wirings SL of the display panel 100. A method of connecting the signal wiring SL and the test wiring TL is not particularly limited. As an example, the signal wiring SL may extend from the display panel 100 up to the test panel 100T to form the test wiring TL. That is, the signal wiring SL and the test wiring TL may be the same wiring. However, the present disclosure is not necessarily limited thereto, and the test wiring TL may be formed separately from the signal wiring SL and then electrically connected thereto by a connection electrode. As an example, a plurality of pads PD1 connected to the drive IC DIC may be formed at ends of the signal wirings SL. The test wirings TL may extend from Ú pads PD1 to the test panel 100T.

In the present specification, the connection of the signal wiring SL and the test wiring TL may include not only a case in which the signal wiring SL and the test wiring TL are formed of the same wiring, but also a case in which the signal wiring SL and the test wiring TL are separately manufactured from each other and then connected by a connection electrode or the like.

The plurality of test wirings TL may be connected to the test pads TP. Thus, the performance of the panel may be measured through the test wiring TL. The number and positions of the test wirings TL and the test pads TP may be appropriately adjusted to perform an auto probe process.

According to the embodiment, a mother substrate may be separated into a plurality of display panels 100 by etching a glass substrate 10. That is, when the glass substrate 10 at a lower side is first etched along a first cutting line CL1 and then a laser is irradiated along the first cutting line CL1, the plurality of display panels 100 may be separated.

Each of the display panels 100 may be in a state in which the test panel 100T is connected thereto. In addition, a sub-etching region EA2 may be formed between the display panel 100 and the test panel 100T. The sub-etching region EA2 may be a region in which the glass substrate 10 is removed in advance. This is because, when a process of etching the glass substrate between the display panel 100 and the test panel 100T is performed again after each panel is separated, the number of processes increases.

According to the embodiment, the substrate 10 may be selectively etched by forming a mask in the remaining region except for a region to be etched in a lower portion of the substrate 10 and exposing the lower portion of the substrate 10 to an etchant. Thus, while forming a main etching region EA1 along the first cutting line CL1, the sub-etching region EA2 may also be formed between the display panel 100 and the test panel 100T.

Thereafter, when the test of the display panel is completed through the test pads TP, the test panel 100T may be removed by irradiating a laser along a second cutting line CL2 on the sub-etching region EA2.

The display panel 100 may include a circuit part 13 disposed on a substrate 10 and an element part 15 disposed on the circuit part 13. The element part 15 may be covered by an encapsulation part 17, and a cover glass may be disposed on the encapsulation part 17.

According to the embodiment, the substrate 10 may include a glass material. That is, the substrate 10 according to the embodiment may have a predetermined strength.

The circuit part 13 may include a pixel circuit connected to wirings such as data lines, gate lines, power lines, and the like, a gate driving part connected to the gate lines, and the like.

The circuit part 13 may include circuit elements such as a transistor implemented as a TFT, a capacitor, and the like. The wirings and circuit elements of the circuit part 13 may be implemented with a plurality of insulating layers, two or more metal layers separated from each other with the insulating layers therebetween, and an active layer including a semiconductor material.

The element part 15 may have a device structure such as an OLED display, a quantum dot display, a micro light-emitting diode (LED) display, or the like. Hereinafter, an OLED structure including an organic compound layer will be described as an example.

The organic compound layer may include a hole injection layer (HIL), a hole transport layer (HTL), an emission layer (EML), an electron transport layer (ETL), and an electron injection layer (EIL), but the present disclosure is not limited thereto.

When a voltage is applied to the anode and the cathode of the OLED, holes passing through the hole transport layer HTL and electrons passing through the electron transport layer ETL move to the emission layer EML to create excitons and thus, visible light is emitted from the emission layer EML.

The element part 15 may further include a color filter array disposed on the pixels that selectively transmit light of red, green, and blue wavelengths.

The element part 15 may be covered by a protective film, and the protective film may be covered by the encapsulation part 17. The protective film and the encapsulation part 17 may have a structure in which organic insulating films and inorganic insulating films are alternately stacked. The inorganic insulating film may block the penetration of moisture or oxygen. An organic insulating film OL1 may planarize a surface of the inorganic insulating film. Accordingly, when the organic insulating film OL1 and the inorganic insulating film are stacked in multiple layers, a moving path of moisture or oxygen is longer than that in a single layer, so that the penetration of moisture/oxygen affecting the element part 15 may be effectively blocked.

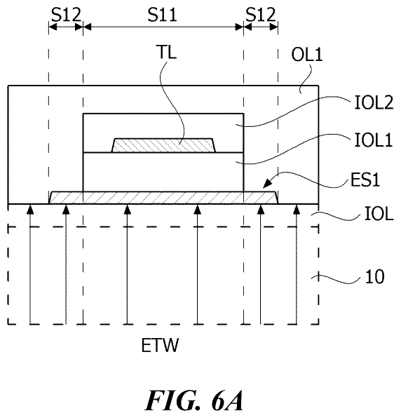

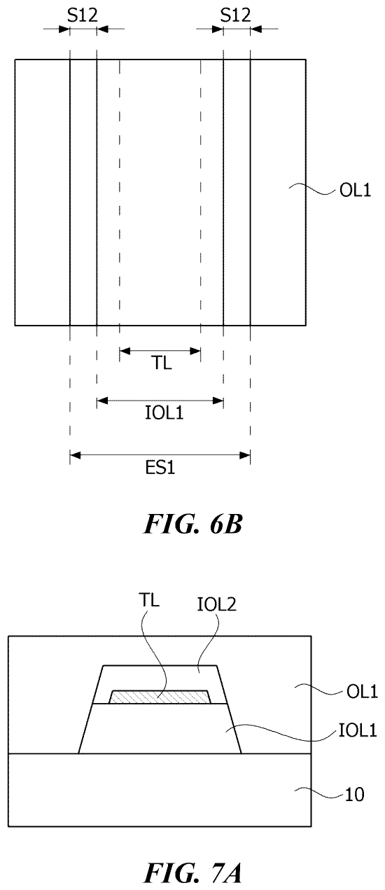

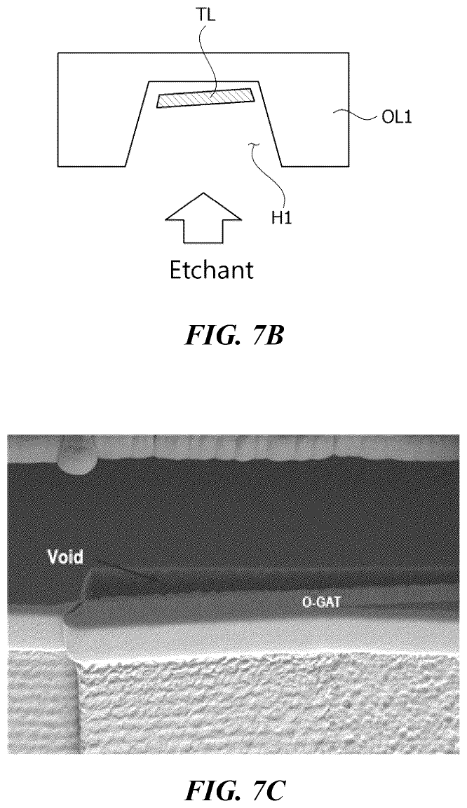

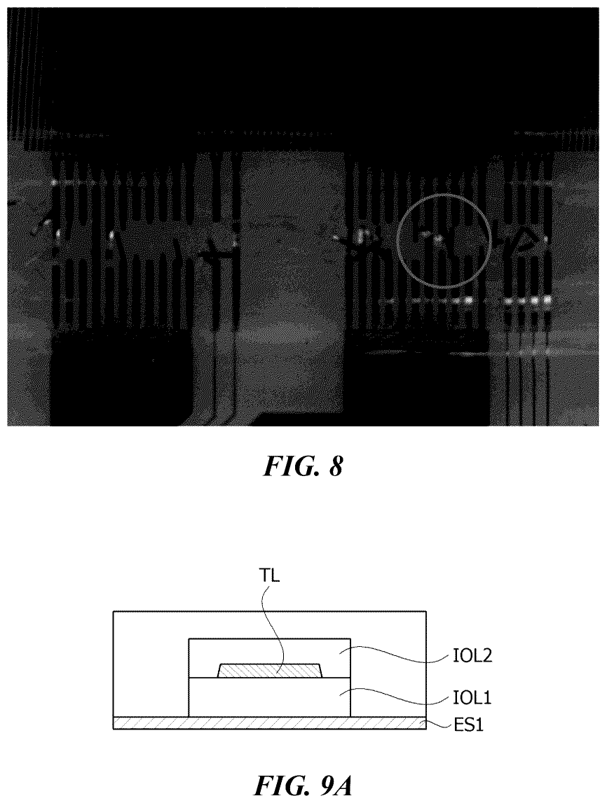

FIG. 4 is a view illustrating a final cross-sectional structure of the panel from which a test region is cut out. FIG. 5 is a cross-sectional view taken along line X-X′ of FIG. 2. FIG. 6A is a view illustrating a test wiring TL structure according to a first embodiment of the present disclosure. FIG. 6B is a plan view of FIG. 6A.

Referring to FIGS. 3 and 4, the main etching region EA1 and the sub-etching region EA2 may be simultaneously formed through an etching process of the glass substrate. Thus, an inclination formed on a side surface 10a of the substrate of the display panel 100 and an inclination formed on a side surface 12a of the substrate of the test panel 100T may be the same.

The signal wirings SL extending from the display region may be electrically connected to the test wirings TL. The signal wirings SL may include a plurality of data lines, a plurality of gate lines, a driving voltage line, and a reference voltage line. The signal wiring SL may have different structures connected to the test wiring TL depending on the type thereof. As an example, the data line passes through the insulating layer and is connected to the test wiring TL, while the gate line is connected to the test wiring without a separate through electrode.

After the test is completed, the test wiring TL may be cut along the second cutting line CL2. The substrate 10 in the sub-etching region EA2 may be removed and filled with a coating layer 30. The coating layer 30 may protect the region from which the substrate is removed and a lower surface of the substrate. The coating layer 30 may be formed of an organic material including a polyester-based polymer and an acrylic polymer, but various materials capable of protecting the substrate may be selected.

When a cut is made along the second cutting line CL2, the test panel 100T may be separated from the display panel 100. The test wiring TL and an etch stop layer ES1 may include protrusion parts TLP1 and ESP1, respectively, protruding further than an end point B1 of an outer side surface of the substrate 10. Here, the coating layer 30 may include an extension part 31 extending up to a lower surface ES1-LS of the protruding etch stop layer ES1. For example, the coating layer 30 is disposed on a lower surface 10LS of the substrate 10, the side surface 10a of the substrate 10, and the lower surface ES1-LS of the etch stop layer ES1 protruding from the side surface 10a of the substrate.

Since the laser vertically cuts along the second cutting line CL2, side surfaces of the test wiring TL, the etch stop layer ES1, and the coating layer may be disposed on the same plane, e.g., coplanar with one another. That is, distances by which the test wiring TL, the etch stop layer ES1, and the coating layer 30 protrude from the end point B1 of the outer side surface of the substrate 10 may be the same.

Referring to FIGS. 5, 6A, and 6B, the etch stop layer ES1 may be disposed below each of the plurality of test wirings TL. Thus, an etching solution ETW may be prevented from penetrating up to a lower portion of the test wiring TL when the substrate 10 in the sub-etching region EA2 is removed.

When a lower portion of the substrate 10 comes into contact with the etching solution, the substrate 10 is gradually etched, and layers disposed above the substrate 10 are exposed. Accordingly, various inorganic layers IOL disposed above the substrate 10 may be etched together with the substrate 10 by the etching solution.

However, the etch stop layer ES1 is formed of a metal material having a strong resistance to an etching solution, such as molybdenum (Mo), and thus the etch stop layer ES1 may not be etched or an etching speed may be very slow. Accordingly, a first inorganic insulating film IOL1 disposed on the etch stop layer ES1 may be prevented from being in contact with the etching solution. As a result, an upper portion of the etch stop layer ES1 may be effectively attached to the panel in the process of etching the substrate 10.

The first inorganic insulating film IOL1, the test wiring TL, and a second inorganic insulating film IOL2 may be disposed on the etch stop layer ES1. However, the present disclosure is not necessarily limited thereto, and the second inorganic insulating film IOL2 may be omitted.

A width (S12+S11+S12) of the etch stop layer ES1 may be formed greater than widths of the test wiring TL and the first inorganic insulating film IOL1. Here, the term “width” may be defined as a width in a direction perpendicular to a longitudinal direction of the test wiring TL. Accordingly, the etch stop layer ES1 may include a center region S11 overlapping the first inorganic insulating film IOL1 and an edge region S12 not overlapping, or offsetting from, the first inorganic insulating film IOL1. The center region S11 overlaps the test wiring TL and the edge region S12 does not overlap, or offsets from, the test wiring TL.

The organic insulating film OL1 may be entirely formed on the test wiring TL. The organic insulating film OL1 may cover an upper surface of the second inorganic insulating film IOL2, a side surface of the first inorganic insulating film IOL1, and up to the edge region S12 of the etch stop layer ES1. The organic insulating film OL1 may include various organic materials that are not etched by the etching solution and may be formed by extending various organic insulating films formed in the display region.

According to the embodiment, since the edge region S12 of the etch stop layer ES1 protrudes further outward than the first inorganic insulating film IOL1, and the organic insulating film OL1 covers the edge region S12, a path along which the etching solution comes into contact with the first inorganic insulating film IOL1 may be blocked.

When the width of the etch stop layer ES1 is less than or equal to that of the first inorganic insulating film, the etching solution ETW may penetrate into a gap between the etch stop layer ES1 and the organic insulating film OL1 to etch the first inorganic insulating film IOL1.

At this time, a width of the edge region S12 may be less than a width of the center region S11. When the width of the edge region S12 is too much greater than the width of the center region S11, an area of the metal layer is increased, and thus cracks may be easily generated in the etch stop layer due to external impact.

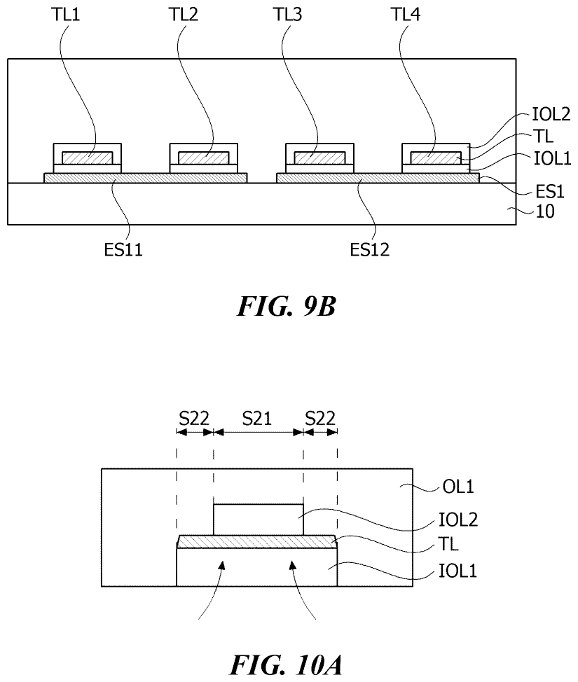

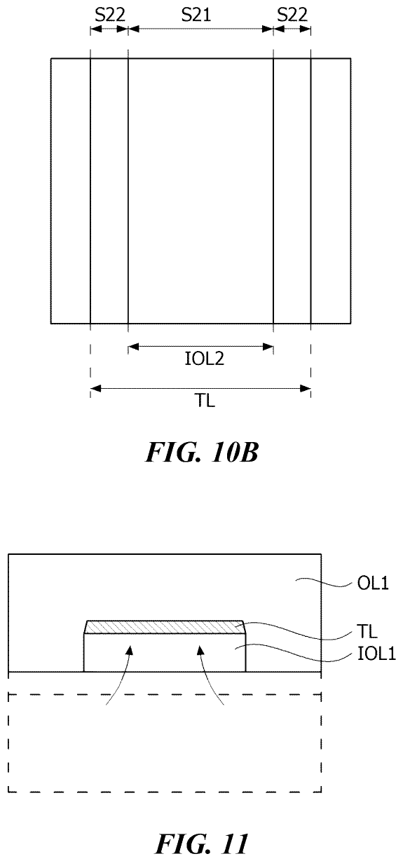

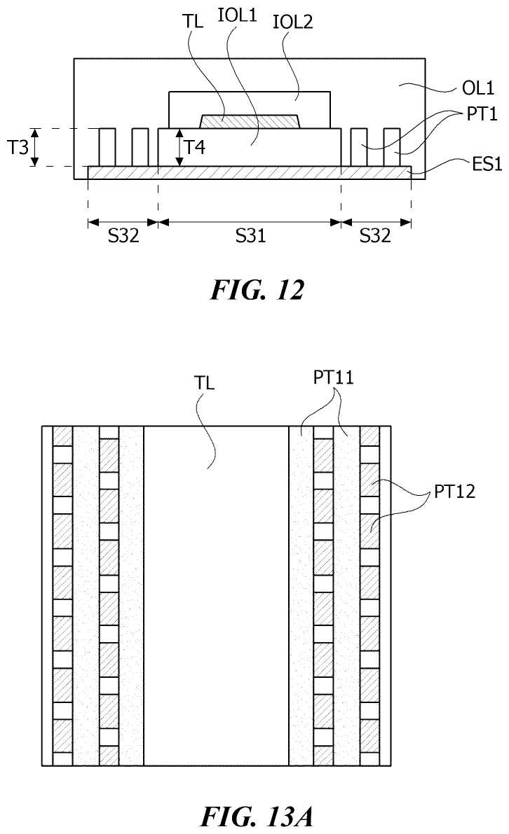

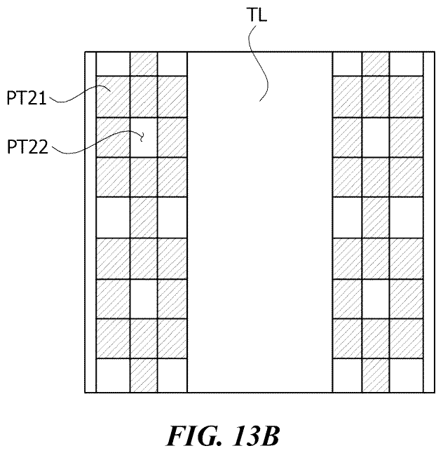

FIG. 7A is a view illustrating a test wiring of a conventional structure. FIG. 7B is a view illustrating a state in which the test wiring is separated from a panel when a substrate is etched. FIG. 7C is a photograph showing a state in which the test wiring is separated from the panel when the substrate is etched. FIG. 8 is a view illustrating a state in which the test wiring is disconnected by etching the substrate.

Referring to FIG. 7A, when only the inorganic insulating film is disposed on the substrate 10 and the test wiring TL without forming the etch stop layer ES1, in the process of etching the substrate 10 as shown in FIGS. 7B and 7C, the etching solution may etch up to the upper inorganic insulating film IOL2 to form pores therein. Thus, the test wiring TL may be separated from the panel together with the inorganic insulating film.

Referring to FIG. 8, it can be seen that, in a process of forming the sub-etched region on the glass substrate, many of the test wirings TL disposed thereon are broken. In this case, it is difficult to perform an accurate test process, and thus, it is difficult to accurately detect whether the display panel 100 is defective. However, according to the embodiment, as described above, it is possible to prevent the inorganic insulating film surrounding the test wiring TL from being etched by the etch stop layer ES1, thereby accurately testing the panel.

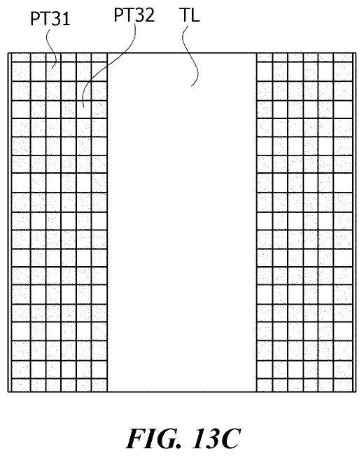

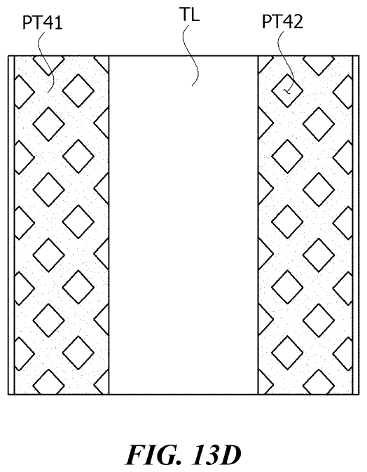

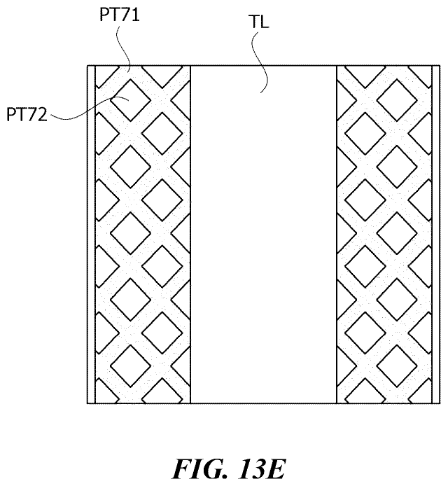

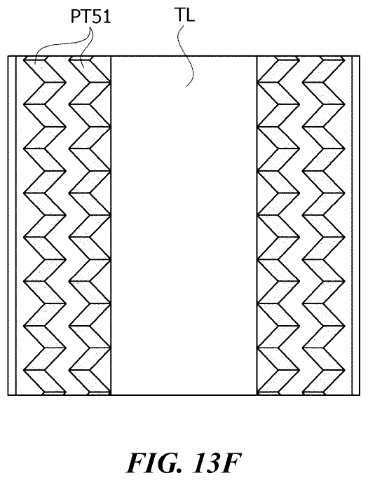

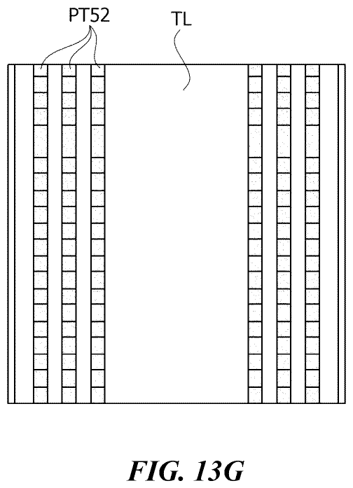

FIG. 9A is a view illustrating a test wiring structure according to a second embodiment of the present disclosure. FIG. 9B is a modified example of FIG. 9A. FIG. 10A is a view illustrating a test wiring structure according to a third embodiment of the present disclosure. FIG. 10B is a plan view of FIG. 10A. FIG. 11 is a view illustrating a test wiring structure according to a fourth embodiment of the present disclosure.

Referring to FIG. 9A, the etch stop layer ES1 according to the embodiment may be entirely formed below a plurality of test wirings TL. In this case, penetration of an etching solution can be easily prevented. However, when a metal layer is formed to have a large area, a crack may be generated in a portion of the etch stop layer ES1 by an external force. Thus, during the etching process, there is a possibility that the etching solution penetrates through the crack to etch the inorganic insulating film, causing defects in the test wiring TL.

Accordingly, as shown in FIG. 9B, an area of an etch stop layer ES1 may be adjusted to cover only some of the plurality of test wirings TL, and there may be multiple etch stop layers ES1 each covering a portion, e.g., one or more, of the plurality of test wirings TL. For example, the test wiring TL includes a first test wiring TL1, a second test wiring TL2, a third test wiring TL3 and a fourth test wiring TL4. The etch stop layer ES1 includes a first etch stop layer ES11 and a second etch stop layer ES12. The first etch stop layer ES111 overlaps the first and second test wirings TL1. TL2, and offsets from the third and fourth test wirings TL3, TL4. The second etch stop layer ES12 overlaps the third and fourth test wirings TL3, TL4, and offsets from the first and second test wirings TL1. TL2. The first test wiring TL1, second test wiring TL2, third test wiring TL3 and fourth test wiring TL4 are on a same level as one another. The first etch stop layer ES11 and second etch stop layer ES12 are on a same level as one another. As an example, the area may be adjusted such that one etch stop layer ES1 is disposed below two to four test wirings TL. In this case, the number of etch stop layers ES1 may be reduced, so that a pattern process may be simplified while preventing a crack from being generated in the etch stop layer ES1.

Referring to FIGS. 10A and 10B, the etch stop layer ES1 may be omitted. As an example, in a state in which the etch stop layer ES1 is omitted, the test wiring TL may be formed on the first inorganic insulating film IOL1, and the second inorganic insulating film IOL2 may be formed on the test wiring TL.

In this case, a width of the second inorganic insulating film IOL2 may be less than a width of the test wiring TL. When the substrate 10 is removed by the etching solution, the first inorganic insulating film IOL1 may also be removed by the etching solution. However, since the test wiring TL is made of a metal material, the test wiring TL may not be etched by the etching solution.

The test wiring TL may include a center region S21 overlapping the second inorganic insulating film IOL2 and an edge region S22 protruding outward from the second inorganic insulating film IOL2.

Since the edge region S22 of the test wiring TL protrudes further than the first inorganic insulating film IOL1, and the organic insulating film OL1 covers the edge region S22 of the test wiring TL, the etching solution may not be in contact with the first inorganic insulating film IOL1. Thus, the test wiring TL may be fixed to the organic insulating film OL1 by the first inorganic insulating film IOL1.

According to the embodiment, the first inorganic insulating film IOL1 disposed below the test wiring TL may be removed during the etching process, but the test wiring TL may be fixed to the panel by the second inorganic insulating film IOL2 disposed above the test wiring TL.

Referring to FIG. 11, in the test wiring TL structure, the test wiring TL may be disposed on the first inorganic insulating film IOL1, and the organic insulating film OL1 may cover upper and side surfaces of the test wiring TL. According to such a structure, the first inorganic insulating film IOL1 may be removed during the etching process, but the test wiring TL may be fixed to the organic insulating film OL1, so that the test wiring TL may be effectively attached to the panel.

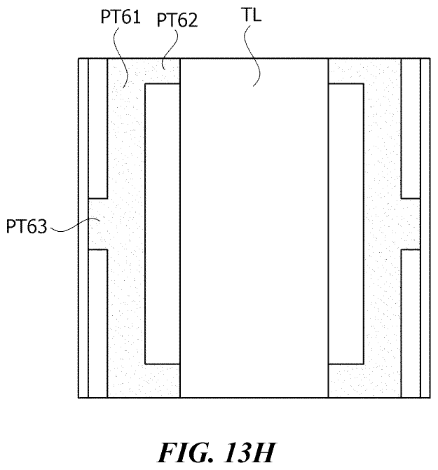

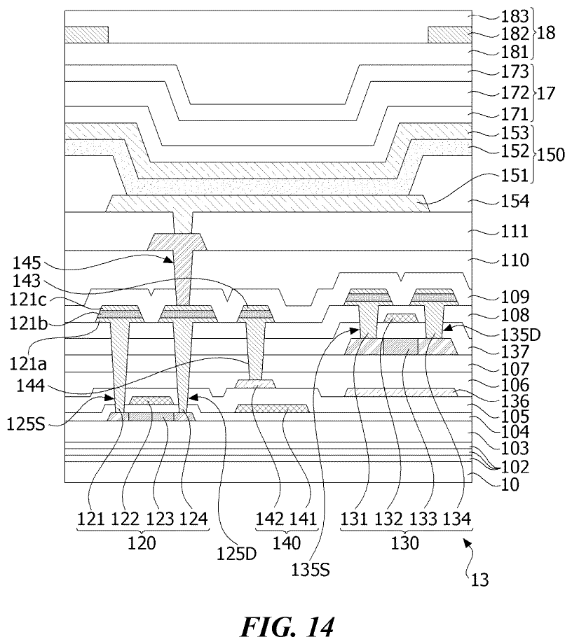

FIG. 12 is a view illustrating a test wiring structure according to a fifth embodiment of the present disclosure. FIGS. 13A to 13H are views illustrating various inorganic insulating film patterns of FIG. 12.

Referring to FIG. 12, the edge region S32 of the etch stop layer ES1 may include an inorganic insulating pattern layer PT1 formed of an inorganic film. The inorganic insulating pattern layer PT1 may include the same material as the first inorganic insulating film IOL1 disposed at a center portion of the etch stop layer ES1.

The inorganic insulating pattern layer PT1 may be formed in the edge region S32 of the etch stop layer ES1 by forming the first inorganic insulating film IOL1 and the second inorganic insulating film IOL2 and then etching the inorganic insulating films. According to such a configuration, a contact area between the organic insulating film OL1 and the inorganic insulating pattern layer PT1 increases, so that an adhesion may increase, which may inhibit the penetration of an etchant during the etching process. In addition, even when the penetration occurs, a time taken to be etched may be delayed by the inorganic insulating pattern layer PT1.

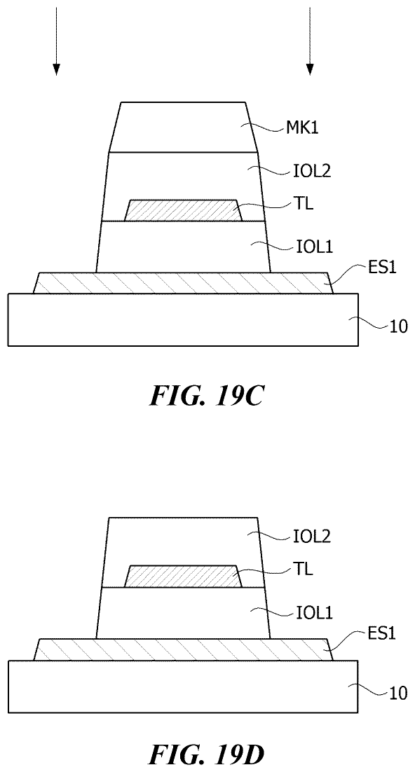

In addition, a portion of the edge region S32 of the etch stop layer ES1 may be etched and removed in the process of etching the inorganic insulating film from thereabove (FIG. 19C), and thus a pattern region is formed in the edge region S32 to prevent the edge region S32 of the etch stop layer ES1 from being excessively removed.

The inorganic insulating pattern layer PT1 may have various patterns that can prevent the edge region S32 of the etch stop layer ES1 from being etched and prevent the penetration of the etching solution. These various patterns may be formed using a mask when etching the inorganic insulating film.

In addition, a half-etching mask or the like may also be used for the mask. The half-etching mask allows an etching beam to pass through only half of an inorganic film, so that a portion of the inorganic film is not etched.

A thickness T3 of the inorganic insulating pattern layer PT1 may vary according to a degree to which the etching beam penetrates the half-etching mask. As an example, when a transmittance of the etching beam is relatively large, the thickness of the inorganic insulating pattern layer PT1 may be less than a thickness T4 of the first inorganic insulating film IOL1. Conversely, when the transmittance of the etching beam is relatively small, the thickness of the inorganic insulating pattern layer PT1 may be greater than the thickness of the first inorganic insulating film IOL1. Although in various cases the thickness T3 of the inorganic insulating pattern layer PT1 is different from the thickness T4 of the first inorganic insulating film IOL1, this does not limit the scope of the disclosure. In some implementations, the thickness T3 of the inorganic insulating pattern layer PT1 may be the same as the thickness T4 of the first inorganic insulating film IOL1.

Referring to FIG. 13A, as for the pattern region, first pattern regions PT11 each formed by extending in a longitudinal direction and second pattern regions PT12 spaced apart from each other by a predetermined interval may be alternately formed. The first pattern regions PT11 may be formed of an inorganic insulating film extending in one direction, and the second pattern regions PT12 may be formed to be spaced apart from each other in one direction by a predetermined interval.

Referring to FIGS. 13B to 13E, the pattern region may be formed as patterns including patterns PT21, PT31, P42, and PT71 continuously arranged in the longitudinal direction, and holes PT22. PT32, PT42, and PT72 formed at a predetermined interval. The holes may be formed regularly or randomly.

Referring to FIGS. 13F and 13G, the pattern region may be formed in the shape of lines spaced apart at a predetermined interval, and the lines may have a zigzag pattern PT51 or a spaced line shape PT52. In addition, a width of each of the lines may be different from each other. Referring to FIG. 13H, the pattern region may include a pattern line PT61 of which both ends PT62 are bent and a partial region PT63 protrudes.

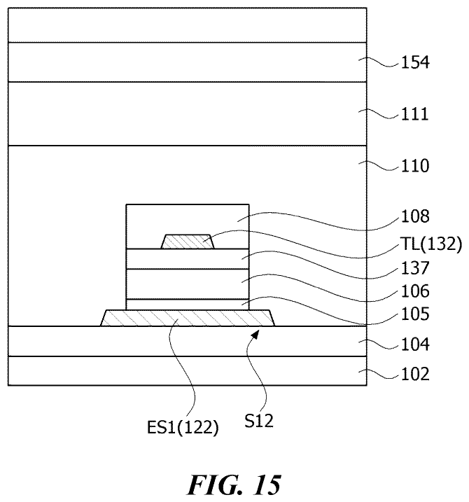

FIG. 14 is a view illustrating a cross section of the display region.

Referring to FIG. 14, the display region DA may include a substrate 10, a multi-buffer layer 102, and an active buffer layer 103, and a first transistor 120 may be disposed on the active buffer layer 103.

A lower gate insulating film 104 may be disposed to insulate a first semiconductor layer 123 constituting the first transistor 120 from a first gate electrode 122 on the first semiconductor layer 123. A first lower interlayer insulating film 105 and a second lower interlayer insulating film 106 may be sequentially disposed on the first gate electrode 122, and an upper buffer layer 107 may be disposed thereon.

The multi-buffer layer 102 may delay the diffusion of moisture or oxygen penetrating into the substrate 10, and may be formed by alternately stacking silicon nitride (SiNx) and silicon oxide (SiOx) at least once.

The active buffer layer 103 may protect the first semiconductor layer 123, and serve to block various types of defects introduced from the substrate 10. The active buffer layer 103 may be formed of a-Si, silicon nitride (SiNx), silicon oxide (SiOx), or the like.

The first semiconductor layer 123 of the first transistor 120 may be formed of a polycrystalline semiconductor layer, and the first semiconductor layer 123 may include a channel region, a source region, and a drain region.

The polycrystalline semiconductor layer has higher mobility than an amorphous semiconductor layer and an oxide semiconductor layer, and thus has low energy power consumption and excellent reliability. These advantages allow the polycrystalline semiconductor layer to be used for a driving transistor.

The first gate electrode 122 may be disposed on the lower gate insulating film 104 and may be disposed to overlap the first semiconductor layer 123.

A second transistor 130 may be disposed on the upper buffer layer 107, and a light blocking layer 136 may be disposed below a region corresponding to the second transistor 130.

The light blocking layer 136 may be disposed on the first lower interlayer insulating film 105 in a region corresponding to the second transistor 130, and a second semiconductor layer 133 of the second transistor 130 may be disposed on the second lower interlayer insulating film 106 and the upper buffer layer 107 so as to overlap the light blocking layer 136.

An upper gate insulating layer 137 for insulating a second gate electrode 132 and the second semiconductor layer 133 may be disposed on the second semiconductor layer 133.

An upper interlayer insulating film 108 may be disposed on the second gate electrode 132. Each of the first gate electrode 122 and the second gate electrode 132 may be formed as a single layer or a multi-layer made of one selected from among molybdenum (Mo), aluminum (Al), chromium (Cr), gold (Au), titanium (Ti), nickel (Ni), neodymium (Nd), and copper (Cu), or an alloy thereof, but the present disclosure is not limited thereto.

The first and second lower interlayer insulating films 105 and 106 may be formed of inorganic insulating films having a higher hydrogen particle content than the upper interlayer insulating film 108. For example, the first and second lower interlayer insulating films 105 and 106 may be made of silicon nitride (SiNx) formed through a deposition process using NH3 gas, and the upper interlayer insulating film 108 may be made of silicon oxide (SiOx). Hydrogen particles included in the first and second lower interlayer insulating films 105 and 106 may be diffused into the polycrystalline semiconductor layer during a hydrogenation process to fill pores in the polycrystalline semiconductor layer with hydrogen. Accordingly, the polycrystalline semiconductor layer may be stabilized, thereby preventing degradation in characteristics of the first transistor 120.

After an activation and hydrogenation process of the first semiconductor layer 123 of the first transistor 120, the second semiconductor layer 133 of the second transistor 130 may be formed, and in this case, the second semiconductor layer 133 may be made of an oxide semiconductor. Since the second semiconductor layer 133 is not exposed to a high-temperature atmosphere of the activation and hydrogenation process of the first semiconductor layer 123, damage to the second semiconductor layer 133 may be prevented, thereby improving reliability.

After the upper interlayer insulating film 108 is disposed, a first source contact hole 125S and a first drain contact hole 125D may be respectively formed to correspond to the source region and the drain region of the first transistor, and a second source contact hole 135S and a second drain contact hole 135D may be respectively formed to correspond to a source region and a drain region of the second transistor 130.

The first source contact hole 125S and the first drain contact hole 125D may be continuously formed from the upper interlayer insulating film 108 to the lower gate insulating film 104, and the second source contact hole 135S and the second drain contact hole 135D may also be formed in the second transistor 130.

A first source electrode 121 and a first drain electrode 124 corresponding to the first transistor 120 and a second source electrode 131 and a second drain electrode 134 corresponding to the second transistor 130 may be formed at the same time, thereby reducing the number of processes of forming the source and drain electrodes of each of the first transistor 120 and the second transistor 130.

The first source and drain electrodes 121 and 124 and the second source and drain electrodes 131 and 134 may be formed as a single layer or a multi-layer made of at least one selected from among molybdenum (Mo), aluminum (Al), chromium (Cr), gold (Au), titanium (Ti), nickel (Ni), neodymium (Nd), and copper (Cu), or an alloy thereof, but the present disclosure is not limited thereto.

The first source and drain electrodes 121 and 124 and the second source and drain electrodes 131 and 134 may have a three-layered structure, and for example, the first source electrode 121 may include a first layer 121a, a second layer 121b, and a third layer 121c, and other source and drain electrodes may have the same structure as the first source electrode 121.

A storage capacitor 140 may be disposed between the first transistor 120 and the second transistor 130. The storage capacitor 140 may be formed by overlapping a storage lower electrode 141 and a storage upper electrode 142 with the first lower interlayer insulating film 105 interposed therebetween.

The storage lower electrode 141 may be positioned on the lower gate insulating film 104, formed on the same layer as the first gate electrode 122, and made of the same material as the first gate electrode 122. The storage upper electrode 142 may be electrically connected to a pixel circuit through a storage supply line 143. The storage upper electrode 142 may be formed on the same layer as the light blocking layer 136 and made of the same material as the light blocking layer 136. The storage upper electrode 142 is exposed through a storage contact hole 144 passing through the second lower interlayer insulating film 106, the upper buffer layer 107, the upper gate insulating layer 137, and the upper interlayer insulating film 108 and is connected to the storage supply line 143.

Although the storage upper electrode 142 is spaced apart from the light blocking layer 136, the storage upper electrode 142 may be connected to the light blocking layer 136 to be formed integrally with the light blocking layer 136. The storage supply line 143 may be formed to be coplanar with the first source and drain electrodes 121 and 124 and the second source and drain electrodes 131 and 134 and made of the same material as the first source and drain electrodes 121 and 124 and the second source and drain electrodes 131 and 134, and accordingly, the storage supply line 143 may be formed simultaneously with the first source and drain electrodes 121 and 124 and the second source and drain electrodes 131 and 134 through the same mask process.

A protective film 109 may be formed by depositing an inorganic insulating material such as SiNx or SiOx on an entire surface of the substrate 10 on which the first source and drain electrodes 121 and 124, the second source and drain electrodes 131 and 134, and the storage supply line 143 are formed.

A first planarization layer 110 may be formed on the protective film 109. Specifically, the first planarization layer 110 may be disposed by applying an organic insulating material such as an acrylic-based resin onto the entire surface of the protective film 109.

After the protective film 109 and the first planarization layer 110 are disposed, a contact hole exposing the first source electrode 121 or the first drain electrode 124 of the first transistor 120 may be formed through a photolithography process. A connection electrode 145 made of a material including Mo, Ti, Cu, AlNd, Al, Cr, or an alloy thereof may be disposed in a region of the contact hole exposing the first drain electrode 124.

A second planarization layer 111 may be disposed on the connection electrode 145, and a contact hole exposing the connection electrode 145 may be formed in the second planarization layer 111 to arrange a light-emitting element 150 connected to the first transistor 120.

The light-emitting element 150 may include an anode 151 connected to the first drain electrode 124 of the first transistor 120, at least one light-emitting stack 152 formed on the anode 151, and a cathode 153 formed on the light-emitting stack 152.

The light-emitting stack 152 may include a hole injection layer, a hole transport layer, an emission layer, an electron transport layer, and an electron injection layer, and in a tandem structure in which a plurality of emission layers overlap each other, a charge generation layer may be additionally disposed between the emission layer and the emission layer. The emission layer may emit light having different colors for each subpixel.

The anode 151 may be connected to the connection electrode 145 exposed through a contact hole passing through the second planarization layer 111. The anode 151 may be formed in a multi-layered structure including a transparent conductive film and an opaque conductive film having high reflection efficiency. The transparent conductive film may be made of a material having a relatively large work function value, such as indium-tin-oxide (ITO) or indium-zinc-oxide (IZO), and the opaque conductive film may have a single-layered or multi-layered structure including Al. Ag. Cu, Pb, Mo, Ti, or an alloy thereof.

For example, the anode 151 may be formed in a structure in which a transparent conductive film, an opaque conductive film, and a transparent conductive film are sequentially stacked or in a structure in which a transparent conductive film and an opaque conductive film are sequentially stacked.

The anode 151 may be disposed in an emission region provided by a bank 154 as well as on the second planarization layer 111 to overlap a pixel circuit region in which the first and second transistors 120 and 130 and the storage capacitor 140 are disposed, thereby increasing an area for emitting light.

The light-emitting stack 152 may be formed by stacking the hole transport layer, the organic emission layer, and the electron transport layer on the anode 151 in the order or reverse order. In addition, the light-emitting stack 152 may further include a charge generation layer and may include first and second light-emitting stacks facing each other with the charge generation layer interposed therebetween.

The bank 154 may be formed to expose the anode 151. The bank 154 may be made of an organic material such as photoacrylic and may include a translucent material, but the present disclosure is not limited thereto. The bank 154 may be made of an opaque material to prevent light interference between the subpixels.

The cathode 153 may be formed on an upper surface of the light-emitting stack 152 to face the anode 151 with the light-emitting stack 152 interposed therebetween. When the cathode 153 is applied to a top emission type organic light-emitting display device, the cathode 153 may be formed of a transparent conductive film by thinly forming ITO, IZO, or magnesium-silver (Mg—Ag).

An encapsulation part 17 for protecting the light-emitting element 150 may be formed on the cathode 153. Since the light-emitting element 150 reacts with external moisture or oxygen due to the characteristics of an organic material of the light-emitting stack 152, dark-spots or pixel shrinkage may occur. In order to prevent the dark-spots or pixel shrinkage, the encapsulation part 17 may be disposed on the cathode 153.

The encapsulation part 17 may include a first inorganic insulating film 171, a foreign material compensation layer 172, and a second inorganic insulating film 173.

A touch part 18 may be disposed on an upper portion on which the encapsulation part 17 is formed. The touch part 18 may include a first touch planarization layer 181, a touch electrode 182, and a second touch planarization layer 183. The first touch planarization layer 181 and the second touch planarization layer 183 may be disposed to eliminate a stepped portion at a point at which the touch electrode 182 is disposed and to allow the touch electrode 182 to be electrically insulated well.

According to embodiments, by disposing the first transistor 120 made of low-temperature polycrystalline silicon and the second transistor 130 made of an oxide semiconductor in different layers, thin-film transistors (TFTs) having different driving characteristics may be disposed in the display device 100. However, the present disclosure is not necessarily limited thereto, and only the thin-film transistors having the same driving characteristic may be used.

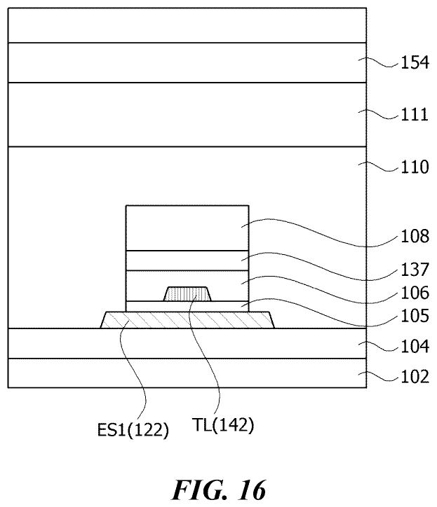

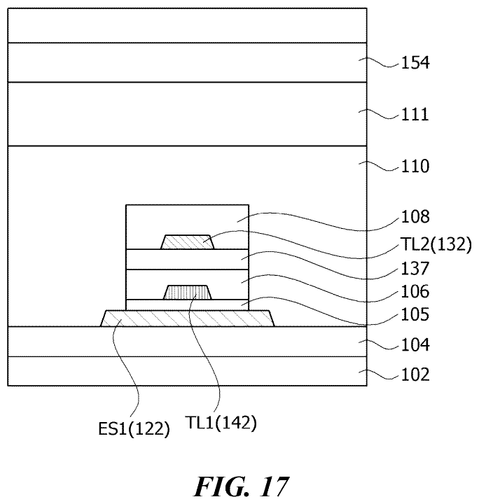

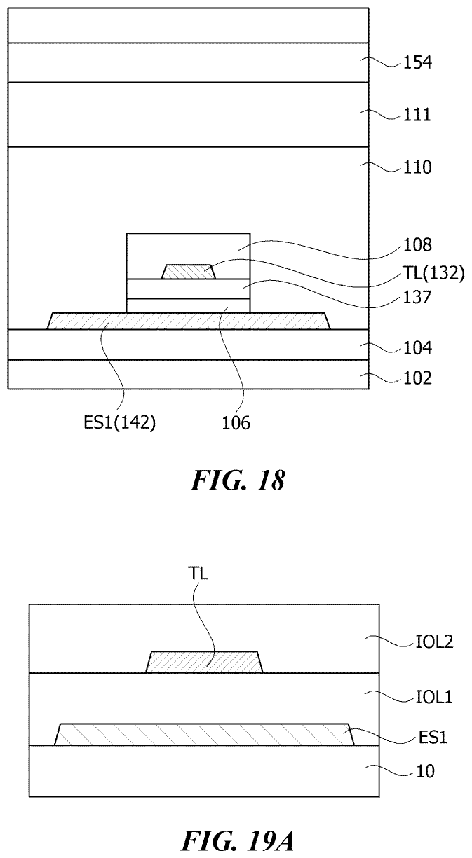

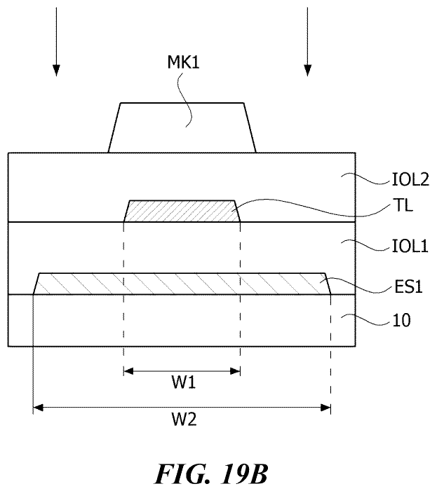

FIG. 15 is a view illustrating a test wiring structure according to a sixth embodiment of the present disclosure. FIG. 16 is a view illustrating a test wiring structure according to a seventh embodiment of the present disclosure. FIG. 17 is a view illustrating a test wiring structure according to an eighth embodiment of the present disclosure. FIG. 18 is a view illustrating a test wiring structure according to a ninth embodiment of the present disclosure.

Referring to FIG. 15, the etch stop layer ES1 may be formed on the same layer as the first gate electrode 122 of the display region. In addition, the test wiring TL may be formed on the same layer as the second gate electrode 132. The first inorganic insulating film IOL1 including a plurality of layers may be formed on the first gate electrode 122. As an example, the plurality of inorganic insulating films may be formed on the same layer as the first lower interlayer insulating film 105 and the second lower interlayer insulating film 106 of the display region.

In addition, the second inorganic insulating film IOL2 formed on the test wiring TL may be the same inorganic insulating film as the upper interlayer insulating film 108 of the display region.

A width of the etch stop layer ES1 may be greater than a width of each of the test wiring TL and the inorganic insulating film. Thus, the etch stop layer ES1 may include the edge region S12 protruding outward from the inorganic insulating film.

The organic insulating film OL1 may cover the first inorganic insulating film IOL1, the second inorganic insulating film IOL2, and the etch stop layer ES1. The organic insulating film OL1 may be the first planarization layer 110 of the display region. However, each of the inorganic insulating films and the organic insulating film may be freely selected from various inorganic insulating films and organic insulating films of the display region.

Referring to FIG. 16, the test wiring TL may be formed by extending the storage upper electrode 142. In this case, the inorganic insulating film disposed between the etch stop layer ES1 and the test wiring TL may be the first lower interlayer insulating film 105. However, the present disclosure is not necessarily limited thereto, and various insulating films disposed between the storage upper electrode and the first gate electrode may be applied without limitation.

Referring to FIG. 17, a pair of test wirings TL may be formed by extending the storage upper electrode 142 and the second gate electrode 132. With this configuration, even when one test wiring TL is cut off, a test may be performed through another test wiring TL.

Referring to FIG. 18, the etch stop layer ES1 may be formed using the storage upper electrode 142, and the test wiring TL may be formed using the second gate electrode 132. In this case, the first inorganic insulating film IOL1 disposed between the etch stop layer ES1 and the test wiring TL may be the second lower interlayer insulating film 106 or the upper gate insulating layer 137.

In this way, in the structure of the test wiring TL, each of the etch stop layer ES1 and the test wiring TL may be formed using any one of the plurality of metal layers formed in the display region, and the inorganic insulating film may be disposed therebetween. In addition, the etch stop layer ES1 may be covered with an organic film such as the first planarization layer and the bank layer to prevent an etching solution from penetrating therethrough.

FIGS. 19A to 19G are views illustrating a process of forming the test wiring TL.

Referring to FIG. 19A, when the display region is formed on the substrate 10, a test region may also be formed. When the first gate electrode of the display region is formed as described above, the etch stop layer ES1 may be simultaneously formed in the test region. Thereafter, when the second gate electrode is formed in the display region, the test wiring TL may be formed in the test region. Various inorganic insulating films disposed in the display region may be formed to extend between the etch stop layer ES1 and the test wiring TL.

Referring to FIG. 19B, a mask MK1 may be disposed on the second inorganic insulating film IOL2, and the inorganic film may be etched. The method of etching the inorganic film is not particularly limited. Various dry etching methods used for etching a semiconductor may be applied without limitation.

Referring to FIG. 19C, the first inorganic insulating film IOL1 and the second inorganic insulating film IOL2 not covered by the mask MK1 may be removed. Thus, the edge region S12 of the etch stop layer ES1 may be exposed to the outside. Thereafter, the mask is removed as shown in FIG. 19D, and a signal wiring layer SD may be entirely formed as shown in FIG. 19E.

The signal wiring layer SD may be formed entirely on a display panel region and a test panel region. Thereafter, the signal wiring layer SD may be patterned in the panel region to form a signal wiring SL and may be entirely removed from the test panel. The signal wiring SL may be electrically connected to the test wiring TL through a through electrode.

As shown in FIG. 19F, in the process of removing the signal wiring layer SD, a thickness T2 of the edge region S12 of the etch stop layer ES1 may be relatively smaller than a thickness T1 of the center region S11. Thereafter, as shown in FIG. 19G, an organic film may be entirely formed on the test wiring TL.

In another embodiment, the signal wiring layer SD may not be etched. Thus, the signal wiring layer SD may remain on the second inorganic insulating film IOL2. In this case, since the remaining signal wiring layer SD entirely surrounds an outer side of the test wiring TL, the test wiring TL may be protected from an etchant.

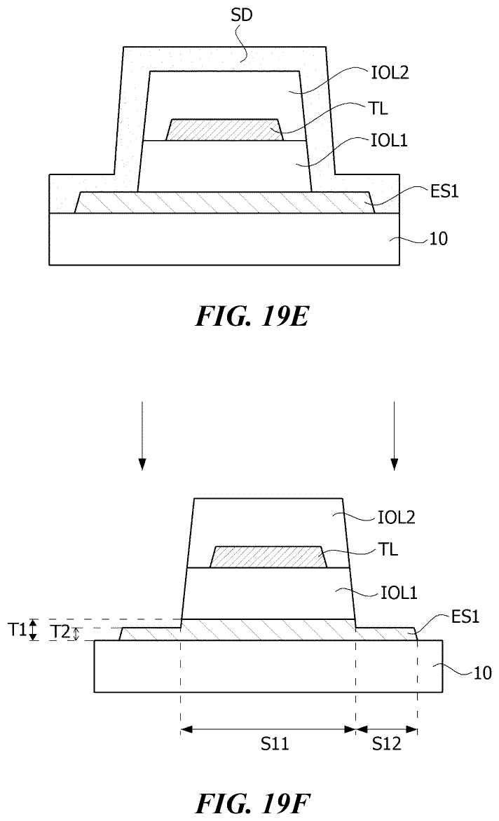

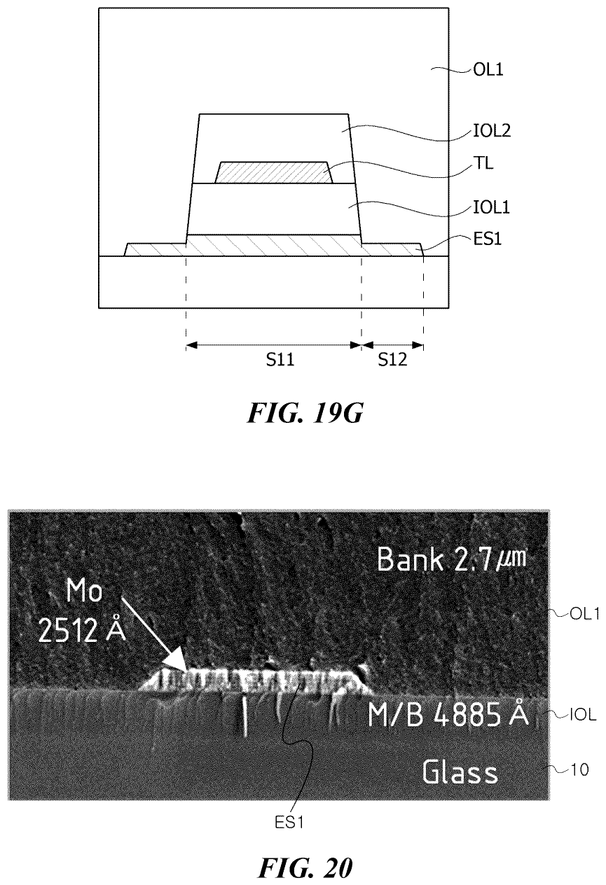

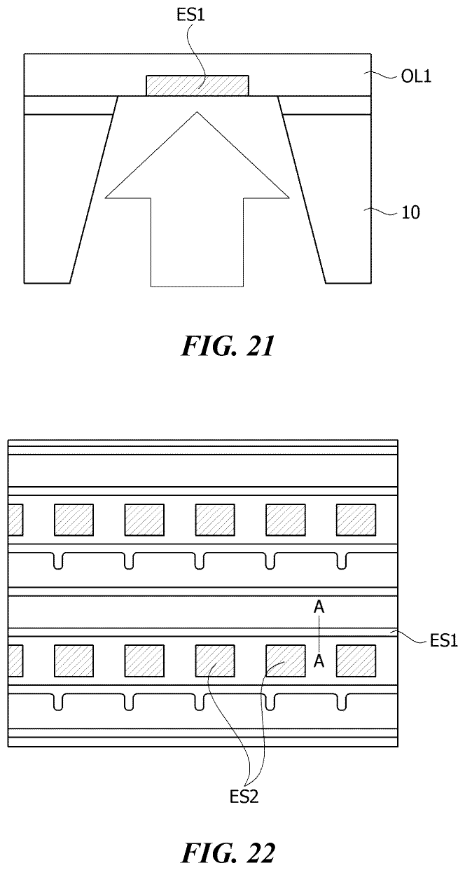

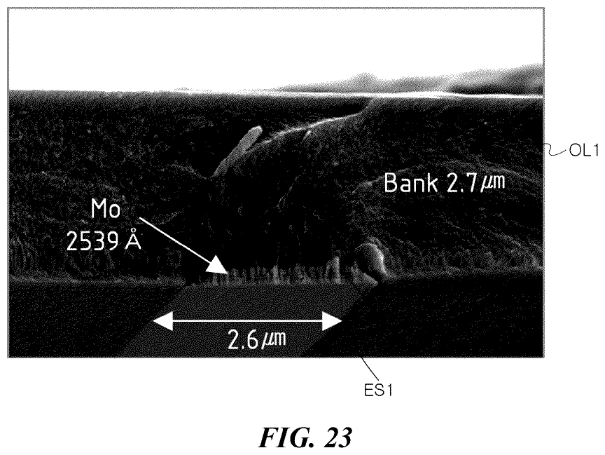

FIG. 20 is a photograph showing a manufactured test wiring. FIG. 21 is a view illustrating a state in which a lower portion of the substrate is etched. FIG. 22 is a photograph illustrating a cross section of a test wiring region after the substrate is removed. FIG. 23 is a photograph showing a cross section taken along line A-A of FIG. 22.

Referring to FIGS. 20 and 21, an etch stop layer ES1 is formed on a substrate 10, a bank layer, which is an organic insulating film OL1, was formed on the etch stop layer ES1, and then a lower portion of the substrate 10 was partially etched.

Referring to FIGS. 22 and 23, it can be seen that the etch stop layer ES1 and an etch stop pattern ES2 are still attached to the bank layer, which is the organic insulating film OL1, even when the substrate is removed. FIG. 22 is a view when viewed from an arrow direction after the substrate is removed as shown in FIG. 21. Thus, it can be seen that even when the substrate 10 is etched, the etch stop layer ES1 is well attached to the panel, thereby preventing the penetration of an etching solution.

According to an embodiment, it is possible to prevent test wirings from being exposed to an etching solution when a glass substrate is etched. Accordingly, the accuracy of a panel test can be improved.

Further, there is a process optimization advantage of allowing differently shaped opening regions to be formed in a display panel at once when a mother substrate is cut.

Effects of the present disclosure will not be limited to the above-mentioned effects and other unmentioned effects will be clearly understood by those skilled in the art from the example embodiments described herein.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate including a display region and a non-display region;
a signal wiring connected to the display region;
a test wiring connected to the signal wiring; and
an etch stop layer disposed below the test wiring,
wherein a width of the etch stop layer is greater than a width of the test wiring.

2. The display device of claim 1, wherein the etch stop layer includes a center region overlapping the test wiring and an edge region not overlapping the test wiring.

3. The display device of claim 2, wherein a width of the edge region is less than a width of the center region.

4. The display device of claim 2, wherein a thickness of the edge region is less than a thickness of the center region.

5. The display device of claim 2, comprising a first inorganic insulating film disposed between the etch stop layer and the test wiring.

6. The display device of claim 5, comprising an organic insulating film disposed on the test wiring and covering the edge region and a side surface of the etch stop layer.

7. The display device of claim 6, comprising a second inorganic insulating film disposed between the organic insulating film and the test wiring.

8. The display device of claim 1, wherein the test wiring includes a plurality of test wirings connected to a plurality of signal wirings, and
the etch stop layer overlaps one or more test wirings of the plurality of test wirings.

9. The display device of claim 5, comprising an inorganic insulating pattern layer disposed on the edge region of the etch stop layer,
wherein a material of the inorganic insulating pattern layer is a same material of the first inorganic insulating film.

10. The display device of claim 9, wherein a thickness of the inorganic insulating pattern layer is different from a thickness of the first inorganic insulating film.

11. The display device of claim 1, wherein a side surface of the substrate has an inclination, and
the etch stop layer protrudes further outward than the side surface of the substrate.

12. The display device of claim 11, comprising a coating layer disposed on a lower surface of the substrate, the side surface of the substrate, and a lower surface of the etch stop layer protruding from the side surface of the substrate.

13. The display device of claim 12, wherein a side surface of the coating layer is coplanar with a side surface of the etch stop layer.

14. The display device of claim 1, wherein the display region includes a first semiconductor layer, a first gate insulating film disposed on the first semiconductor layer, a first gate electrode disposed on the first gate insulating film, and a first insulating film disposed on the first gate electrode, and
the etch stop layer is formed on a same layer as the first gate electrode.

15. The display device of claim 14, wherein the display region includes a second semiconductor layer disposed on the first insulating film, and a second gate electrode disposed on the second semiconductor layer, and
the test wiring is formed on a same layer as the second gate electrode.

16. A display device comprising:
a substrate including a display region and a non-display region;
a test wiring connected to the display region; and
an etch stop layer disposed below the test wiring,
wherein the etch stop layer protrudes further outward than a side surface of the substrate.

17. The display device of claim 16, wherein the test wiring protrudes further outward than the side surface of the substrate.

18. The display device of claim 17, comprising a coating layer disposed on a lower surface of the substrate, the side surface of the substrate, and a lower surface of the etch stop layer protruding from the side surface of the substrate.

19. The display device of claim 18, wherein a side surface of the coating layer is coplanar with a side surface of the etch stop layer.

20. A display device comprising:
a substrate including a display region and a non-display region;
a test wiring connected to a circuit in the display region; and
an etch stop layer disposed below the test wiring; and
a coating layer on the substrate and in contact with the etch stop layer, a side surface of the coating layer being coplanar with a side surface of the etch stop layer.
